(19) United States
(12) Patent Application Publication
(10) Pub. No.: US 2025/0331201 A1
(43) Pub. Date: Oct. 23, 2025

(54) VARACTOR STRUCTURE

(71) Applicant: United Microelectronics Corp., Hsinchu (TW)

(72) Inventors: Chien-Yi Lee, Hsinchu City (TW); Tse-Pu Chen, Tainan City (TW); Sheng-Huei Dai, Taitung County (TW)

(73) Assignee: United Microelectronics Corp., Hsinchu (TW)

(21) Appl. No.: 18/674,922

(22) Filed: May 27, 2024

(30) Foreign Application Priority Data
Apr. 18, 2024 (CN) 202410469264.5

(51) Int. Cl. H01L 29/93; H01L 21/761; H01L 21/768; H01L 29/66

(52) U.S. Cl. CPC H10D 1/64; H01L 21/761; H01L 21/76829; H10D 1/045

(57) ABSTRACT

A varactor structure including a substrate, a first conductive layer, a second conductive layer, a first dielectric layer, a second dielectric layer, a first doped region, and a second doped region is provided. The first conductive layer is located on the 5 substrate. The second conductive layer is located on the first conductive layer. The first dielectric layer is located between the substrate and the first conductive layer. The second dielectric layer is located between the first conductive layer and the second conductive layer. The first doped region and the second doped region are located in the substrate at two sides of the first conductive layer. The second conductive layer is 10 electrically connected to the first doped region and the second doped region.

### CROSS-REFERENCE TO RELATED APPLICATION

This application claims the priority benefit of China application serial no. 202410469264.5, filed on Apr. 18, 2024. The entirety of the above-mentioned patent application is hereby incorporated by reference herein and made a part of this specification.

### BACKGROUND OF THE INVENTION

### Field of the Invention

The invention relates to a semiconductor structure, and in particular to a varactor structure.

### Description of Related Art

A varactor is a variable capacitance device for which the capacitance value may be adjusted by voltage. The varactor may be integrated into various circuit designs. However, how to improve the quality factor (Q factor) and the unit capacitance of the varactor is the object of continuous efforts.

### SUMMARY OF THE INVENTION

The invention provides a varactor structure having a higher quality factor and a higher unit capacitance.

The invention provides a varactor structure including a substrate, a first conductive layer, a second conductive layer, a first dielectric layer, a second dielectric layer, a first doped region, and a second doped region. The first conductive layer is located on the substrate. The second conductive layer is located on the first conductive layer. The first dielectric layer is located between the substrate and the first conductive layer. The second dielectric layer is located between the first conductive layer and the second conductive layer. The first doped region and the second doped region are located in the substrate at two sides of the first conductive layer. The second conductive layer is electrically connected to the first doped region and the second doped region.

According to an embodiment of the invention, the varactor structure may further include a first conductive wire. The first conductive wire is electrically connected to the second conductive layer, the first doped region, and the second doped region.

According to an embodiment of the invention, in the varactor structure, a top-view pattern of the first conductive wire may include a ring shape.

According to an embodiment of the invention, the varactor structure may further include a first conductive plug, a second conductive plug, and a third conductive plug.

The first conductive plug is located between the first conductive wire and the second conductive layer. The first conductive plug is electrically connected to the first conductive wire and the second conductive layer. The second conductive plug is located between the first conductive wire and the first doped region. The second conductive plug is electrically connected to the first conductive wire and the first doped region. The third conductive plug is located between the first conductive wire and the second doped region. The third conductive plug is electrically connected to the first conductive wire and the second doped region.

According to an embodiment of the invention, the varactor structure may further include a second conductive wire. The second conductive wire is electrically connected to the first conductive layer.

According to an embodiment of the invention, the varactor structure may further include a fourth conductive plug. The fourth conductive plug is located between the second conductive wire and the first conductive layer. The fourth conductive plug is electrically connected to the second conductive wire and the first conductive layer.

According to an embodiment of the invention, in the varactor structure, the first conductive layer and the second conductive layer may be extended in a first direction.

According to an embodiment of the invention, in the varactor structure, a length of the first conductive layer in the first direction may be greater than a length of the second conductive layer in the first direction.

According to an embodiment of the invention, in the varactor structure, the first doped region and the second doped region may be arranged in a second direction. The first direction may be intersected with the second direction.

According to an embodiment of the invention, in the varactor structure, a material of the first conductive layer is, for example, doped polysilicon or a metal.

According to an embodiment of the invention, in the varactor structure, a material of the second conductive layer is, for example, a metal, a metal compound, or a combination thereof.

According to an embodiment of the invention, in the varactor structure, a material of the first dielectric layer is, for example, silicon oxide, a high-k material, or a combination thereof.

According to an embodiment of the invention, in the varactor structure, a material of the second dielectric layer is, for example, a low-k material or a high-k material.

According to an embodiment of the invention, the varactor structure may further include a spacer. The spacer is located on a sidewall of the first conductive layer.

According to an embodiment of the invention, the varactor structure may further include a well region. The well region is located in the substrate. The first doped region and the second doped region may be located in the well region.

According to an embodiment of the invention, in the varactor structure, the first doped region, the second doped region, and the well region may have a same conductivity type.

According to an embodiment of the invention, the varactor structure may further include an isolation structure. The isolation structure is located in the substrate. The isolation structure may define an active region in the substrate.

According to an embodiment of the invention, in the varactor structure, the first doped region and the second doped region may be located in the active region.

According to an embodiment of the invention, the isolation structure is, for example, a shallow trench isolation structure.

According to an embodiment of the invention, the varactor structure may further include a third dielectric layer and a fourth dielectric layer. The third dielectric layer is located between the second dielectric layer and the substrate. The fourth dielectric layer is located on the second dielectric layer.

Based on the above, in the varactor structure provided by the invention, the second conductive layer is located on the first conductive layer, the second dielectric layer is located between the first conductive layer and the second conductive layer, and the second conductive layer is electrically connected to the first doped region and the second doped region. Therefore, the varactor structure provided by the invention may have a higher quality factor and a higher unit capacitance.

In order to make the aforementioned features and advantages of the disclosure more comprehensible, embodiments accompanied with figures are described in detail below.

### BRIEF DESCRIPTION OF THE DRAWINGS

FIG. 1A to FIG. 1D are cross-sectional views of the manufacturing process of a varactor structure according to some embodiments of the invention.

FIG. 2 is a top view of the varactor structure of FIG. 1D.

FIG. 3 is a schematic circuit diagram of the varactor structure of FIG. 1D.

### DESCRIPTION OF THE EMBODIMENTS

Embodiments are provided hereinafter and described in detail with reference to figures. However, the embodiments provided are not intended to limit the scope of the invention. In order to facilitate understanding, the same members are described with the same reference numerals in the following description. In addition, the drawings are for illustration purposes only and are not drawn to original scale. Also, the features in the upper view are not drawn to the same scale as those in the cross-sectional view. In fact, the dimensions of the various features may be arbitrarily increased or reduced for clarity of discussion.

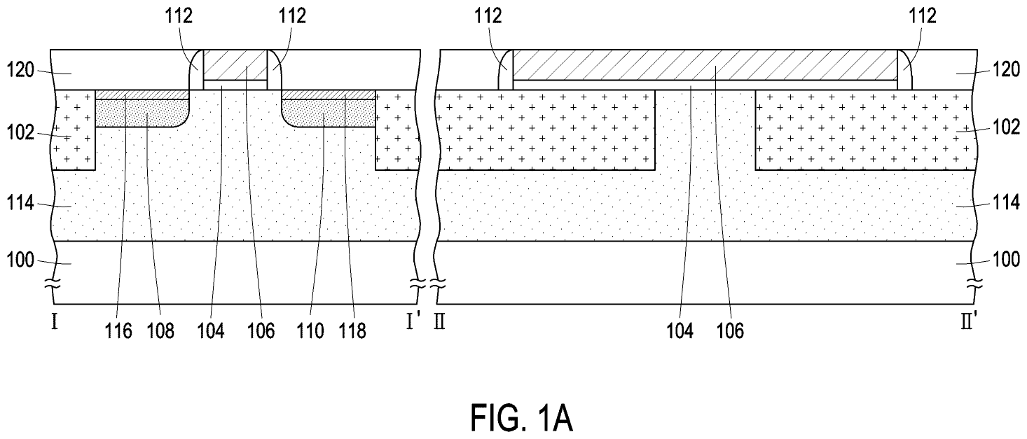

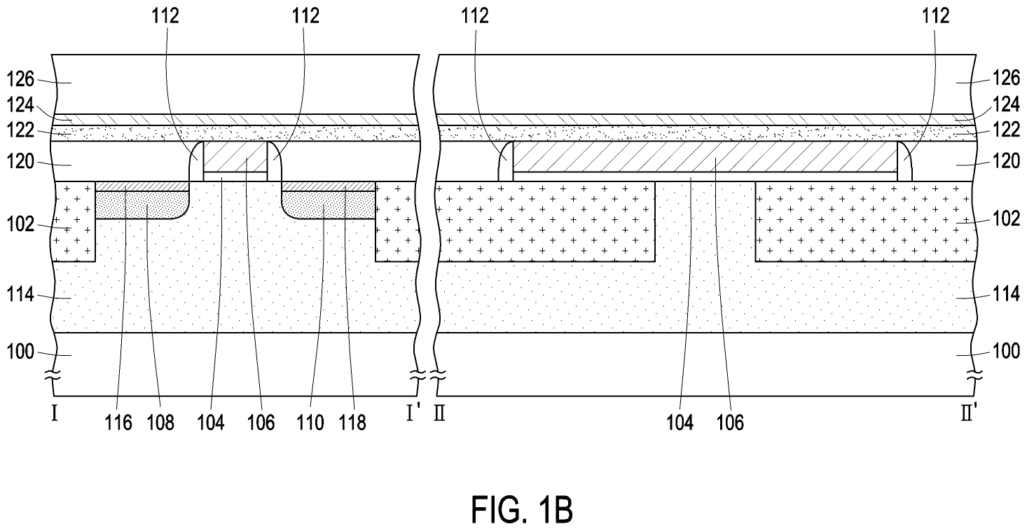

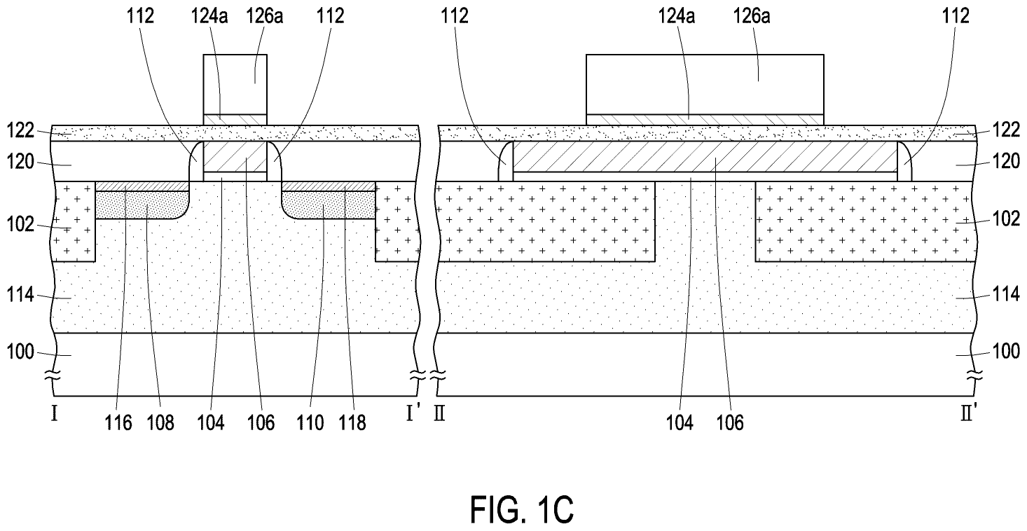

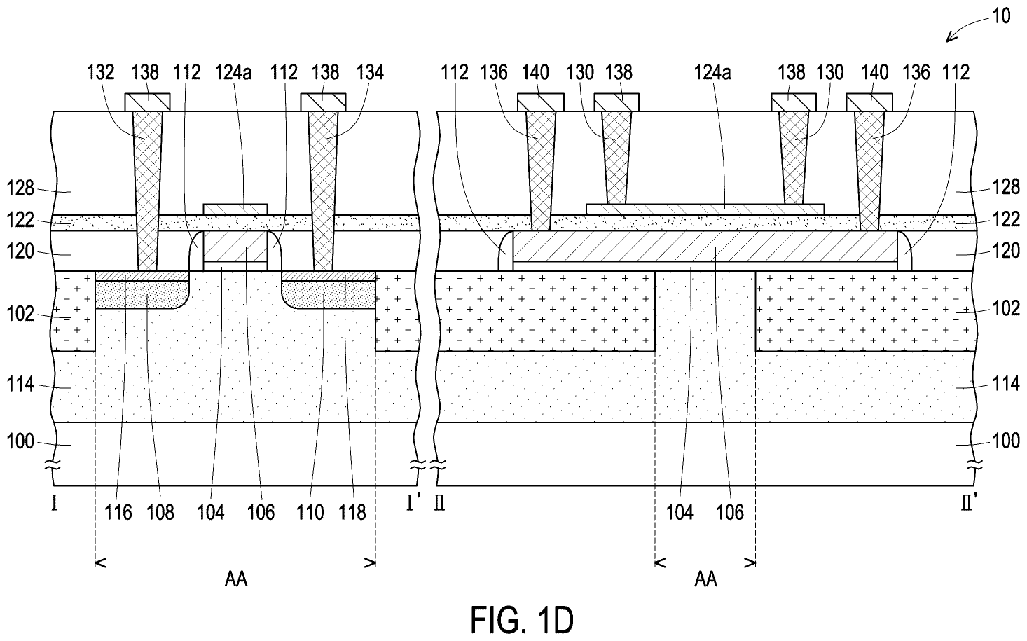

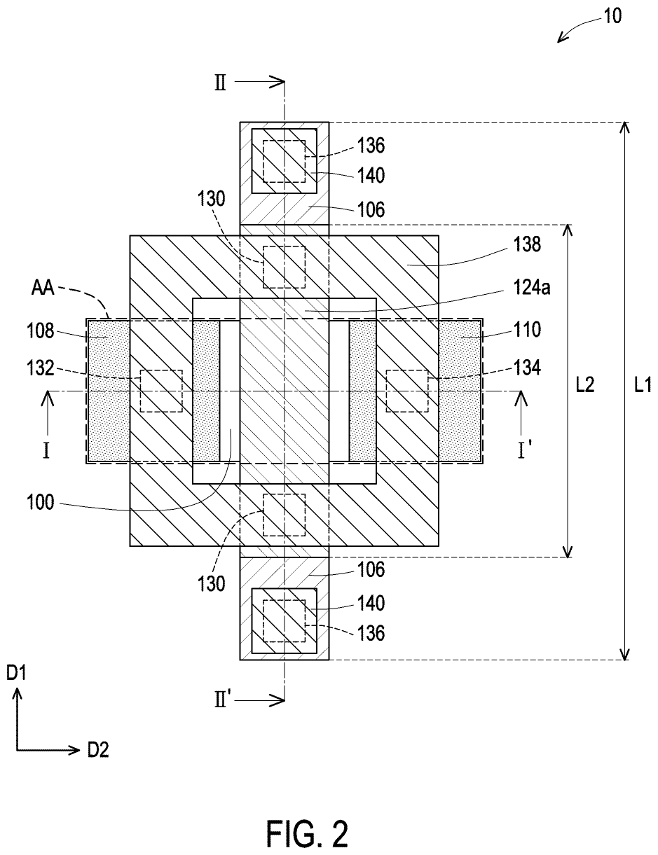

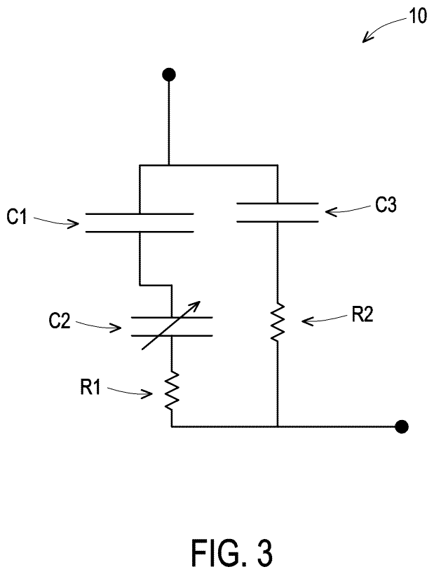

FIG. 1A to FIG. 1D are cross-sectional views of the manufacturing process of a varactor structure according to some embodiments of the invention. FIG. 2 is a top view of the varactor structure of FIG. 1D. FIG. 1A to FIG. 1D are cross-sectional views along section line I-I′ and section line II-II′ in FIG. 2. In FIG. 2, some members in FIG. 1D are omitted to clearly illustrate the arrangement relationship between the members in FIG. 2. FIG. 3 is a schematic circuit diagram of the varactor structure of FIG. 1D.

Referring to FIG. 1A, a substrate 100 is provided. In some embodiments, the substrate 100 may be a semiconductor substrate, such as a silicon substrate. In some embodiments, an isolation structure 102 may be formed in the substrate 100. In some embodiments, the isolation structure 102 is, for example, a shallow trench isolation structure. In some embodiments, the material of the isolation structure 102 is, for example, silicon oxide.

Next, a dielectric layer 104 is formed on the substrate 100. The dielectric layer 104 may be a single-layer structure or a multi-layer structure. In some embodiments, the material of the dielectric layer 104 is, for example, silicon oxide, a high-k material, or a combination thereof.

Then, a conductive layer 106 may be formed on the dielectric layer 104. The conductive layer 106 may be a single-layer structure or a multi-layer structure. In some embodiments, the material of the conductive layer 106 is, for example, doped polysilicon or a metal. In some embodiments, the conductive layer 106 may be used as a gate. In some embodiments, the conductive layer 106 may be a polysilicon gate or a metal gate.

Next, a doped region 108 and a doped region 110 are formed in the substrate 100 at two sides of the conductive layer 106. In some embodiments, the doped region 108 and the doped region 110 may be used as source/drain regions. In some embodiments, the doped region 108 and the doped region 110 may have an N-type conductivity type, but the invention is not limited thereto. In some other embodiments, the doped region 108 and the doped region 110 may have a P-type conductivity type. In some embodiments, a spacer 112 may be formed on the sidewall of the conductive layer 106. The spacer 112 may be a single-layer structure or a multi-layer structure. In some embodiments, the material of the spacer 112 is, for example, silicon oxide, a silicon nitride, or a combination thereof.

In some embodiments, a well region 114 may be formed in the substrate 100. In some embodiments, the doped region 108, the doped region 110, and the well region 114 may have the same conductivity type. In some embodiments, the well region 114 may have an N-type conductivity type, but the invention is not limited thereto. In some other embodiments, the well region 114 may have a P-type conductivity type.

In some embodiments, a metal silicide layer 116 and a metal silicide layer 118 may be formed on the doped region 108 and the doped region 110 respectively. In some embodiments, the material of the metal silicide layer 116 and the metal silicide layer 118 is, for example, nickel silicide or cobalt silicide.

In some embodiments, a dielectric layer 120 may be formed on the isolation structure 102, the spacer 112, the metal silicide layer 116, and the metal silicide layer 118.

The dielectric layer 120 may be a single-layer structure or a multi-layer structure. In some embodiments, the material of the dielectric layer 120 is, for example, silicon oxide, silicon nitride, or a combination thereof. In some embodiments, the forming method of the dielectric layer 120 is a chemical vapor deposition method, for example.

Referring to FIG. 1B, a dielectric layer 122 is formed on the conductive layer 106. The dielectric layer 122 may further be formed on the dielectric layer 120. In some embodiments, the material of the dielectric layer 122 is, for example, a low-k material or a high-k material. In some embodiments, the low-k material is, for example, silicon oxide. In some embodiments, the high-k material is, for example, a metal oxide, such as hafnium oxide (HfO₂), zirconium oxide (ZrO₂), or aluminum oxide (Al₂O₃). In some embodiments, the forming method of the dielectric layer 122 is a chemical vapor deposition method, for example.

Then, a conductive material layer 124 may be formed on the dielectric layer 122. In some embodiments, the material of the conductive material layer 124 is, for example, a metal (e.g., titanium or copper), a metal compound (e.g., titanium nitride), or a combination thereof. In some embodiments, the forming method of the conductive material layer 124 is a chemical vapor deposition method or a physical vapor deposition method, for example.

Then, a hard mask material layer 126 may be formed on the conductive material layer 124. In some embodiments, the material of the hard mask material layer 126 is, for example, silicon nitride. In some embodiments, the forming method of the hard mask material layer 126 is a chemical vapor deposition method, for example.

Referring to FIG. 1C, the hard mask material layer 126 and the conductive material layer 124 may be patterned to form a hard mask layer 126a and a conductive layer 124a. In some embodiments, the material of the hard mask layer 126a is, for example, silicon nitride. In some embodiments, the material of the conductive layer 124a is, for example, a metal (e.g., titanium or copper), a metal compound (e.g., titanium nitride), or a combination thereof. In some embodiments, the hard mask material layer 126 and the conductive material layer 124 may be patterned using a lithography process and an etching process.

Referring to FIG. 1D, the hard mask layer 126a may be removed. In some embodiments, the removal method of the hard mask layer 126a is, for example, a dry etching method.

Next, a dielectric layer 128 may be formed on the dielectric layer 122 and the conductive layer 124a. In some embodiments, the material of the dielectric layer 128 is, for example, silicon oxide. In some embodiments, the forming method of the dielectric layer 128 is a chemical vapor deposition method, for example.

Then, a conductive plug 130, a conductive plug 132, a conductive plug 134, and a conductive plug 136 may be formed. The conductive plug 130 is located in the dielectric layer 128. The conductive plug 130 is electrically connected to the conductive layer 124a. The conductive plug 132 is located in the dielectric layer 128, the dielectric layer 122, and the dielectric layer 120. The conductive plug 132 is electrically connected to the doped region 108. The conductive plug 134 is located in the dielectric layer 128, the dielectric layer 122, and the dielectric layer 120. The conductive plug 134 is electrically connected to the doped region 110. The conductive plug 136 is located in the dielectric layer 128 and the dielectric layer 122. The conductive plug 136 is electrically connected to the conductive layer 106. In some embodiments, the material of the conductive plug 130, the conductive plug 132, the conductive plug 134, and the conductive plug 136 is, for example, tungsten, titanium, titanium nitride, or a combination thereof.

Next, a conductive wire 138 and a conductive wire 140 may be formed. The conductive wire 138 is located on the dielectric layer 128, the conductive plug 130, the conductive plug 132, and the conductive plug 134. The conductive wire 138 is electrically connected to the conductive plug 130, the conductive plug 132, and the conductive plug 134. The conductive wire 140 is located on the dielectric layer 128 and the conductive plug 136. The conductive wire 140 is electrically connected to the conductive plug 136. The material of the conductive wire 138 and the conductive wire 140 is, for example, copper (Cu).

The varactor structure 10 of the above embodiment is described below with reference to FIG. 1D, FIG. 2, and FIG. 3. In addition, although the forming method of the varactor structure 10 is described by taking the above method as an example, the invention is not limited thereto.

Referring to FIG. 1D and FIG. 2, the varactor structure 10 includes the substrate 100, the conductive layer 106, the conductive layer 124a, the dielectric layer 104, the dielectric layer 122, the doped region 108, and the doped region 110. The conductive layer 106 is located on the substrate 100. The conductive layer 124a is located on the conductive layer 106. In some embodiments, as shown in FIG. 2, the conductive layer 106 and the conductive layer 124a may be extended in a direction D1. In some embodiments, a length L1 of the conductive layer 106 in the direction D1 may be greater than a length L2 of the conductive layer 124a in the direction D1. The dielectric layer 104 is located between the substrate 100 and the conductive layer 106. The dielectric layer 122 is located between the conductive layer 106 and the conductive layer 124a. The doped region 108 and the doped region 110 are located in the substrate 100 at two sides of the conductive layer 106. In some embodiments, as shown in FIG. 2, the doped region 108 and the doped region 110 may be arranged in a direction D2. The direction D1 may be intersected with the direction D2. In some embodiments, the direction D1 may be perpendicular to the direction D2. The conductive layer 124a is electrically connected to the doped region 108 and the doped region 110.

In some embodiments, the varactor structure 10 may further include an isolation structure 102. The isolation structure 102 is located in the substrate 100. The isolation structure 102 may define an active region AA in the substrate 100. The doped region 108 and the doped region 110 may be located in the active region AA. In some embodiments, the varactor structure 10 may further include the well region 114. The well region 114 is located in the substrate 100. The doped region 108 and the doped region 110 may be located in the well region 114.

In some embodiments, the varactor structure 10 may further include the spacer 112. The spacer 112 is located on the sidewall of the conductive layer 106. In some embodiments, the varactor structure 10 may further include the metal silicide layer 116 and a metal silicide layer 118. The metal silicide layer 116 is located on the doped region 108. The metal silicide layer 118 is located on the doped region 110.

In some embodiments, the varactor structure 10 may further include the dielectric layer 120 and the dielectric layer 128. The dielectric layer 120 is located between the dielectric layer 122 and the substrate 100. The dielectric layer 120 may further be located on the isolation structure 102, the spacer 112, the metal silicide layer 116, and the metal silicide layer 118. The dielectric layer 128 is located on the dielectric layer 122. The dielectric layer 128 may further be located on the conductive layer 124a.

In some embodiments, the varactor structure 10 may further include the conductive wire 138. The conductive wire 138 is electrically connected to the conductive layer 124a, the doped region 108, and the doped region 110. In some embodiments, as shown in FIG. 2, the top-view pattern of the conductive wire 138 may include a ring shape.

In some embodiments, the varactor structure 10 may further include the conductive plug 130, the conductive plug 132, and the conductive plug 134. The conductive plug 130 is located between the conductive wire 138 and the conductive layer 124a. The conductive plug 130 is electrically connected to the conductive wire 138 and the conductive layer 124a, whereby the conductive wire 138 may be electrically connected to the conductive layer 124a. The conductive plug 132 is located between the conductive wire 138 and the doped region 108. The conductive plug 132 is electrically connected to the conductive wire 138 and the doped region 108, whereby the conductive wire 138 may be electrically connected to the doped region 108. In some embodiments, the conductive plug 132 may be electrically connected to the doped region 108 via the metal silicide layer 116. The conductive plug 134 is located between the conductive wire 138 and the doped region 110. The conductive plug 134 is electrically connected to the conductive wire 138 and the doped region 110, whereby the conductive wire 138 may be electrically connected to the doped region 110. In some embodiments, the conductive plug 134 may be electrically connected to the doped region 110 via the metal silicide layer 118.

In some embodiments, the conductive layer 124a may be electrically connected to the doped region 108 via the conductive plug 130, the conductive wire 138, the conductive plug 132, and the metal silicide layer 116. In some embodiments, the conductive layer 124a may be electrically connected to the doped region 110 via the conductive plug 130, the conductive wire 138, the conductive plug 134, and the metal silicide layer 118.

In some embodiments, the varactor structure 10 may further include the conductive wire 140. The conductive wire 140 is electrically connected to the conductive layer 106. In some embodiments, the varactor structure 10 may further include the conductive plug 136. The conductive plug 136 is located between the conductive wire 140 and the conductive layer 106. The conductive plug 136 is electrically connected to the conductive wire 140 and the conductive layer 106, whereby the conductive wire 140 may be electrically connected to the conductive layer 106.

Moreover, the details of each member in the varactor structure 10 (such as materials, arrangements, forming methods, etc.) are described in detail in the above embodiments and are not described again.

Referring to FIG. 1D and FIG. 3, a capacitor C1 may be a capacitor formed by the conductive layer 106, the dielectric layer 104, and the substrate 100. A variable capacitor C2 may be a variable capacitor formed by a depletion region of the well region 114 directly below the conductive layer 106 (gate). A capacitor C3 may be a capacitor formed by the conductive layer 124a, the dielectric layer 122, and the conductive layer 106. In addition, since the varactor structure 10 may include an additional capacitor C3, the varactor structure 10 may have a higher unit capacitance. A resistor R1 may be a series resistance from the depletion region capacitor to the conductive wire 138. A resistor R2 may be the resistance of the conductive layer 124a. In addition, since the resistor R1 (the resistance of the substrate 100) and the resistor R2 (the resistance of the conductive layer 124a) are connected in parallel, the overall resistance may be reduced, thereby improving the quality factor.

Based on the above embodiments, it may be known that in the varactor structure 10, the conductive layer 124a is located on the conductive layer 106, the dielectric layer 122 is located between the conductive layer 106 and the conductive layer 124a, and the conductive layer 124a is electrically connected to the doped region 108 and the doped region 110. Therefore, the varactor structure 10 may have a higher quality factor and a higher unit capacitance.

Based on the above, the varactor structure of an embodiment above includes the substrate, the first conductive layer, the second conductive layer, the first dielectric layer, the second dielectric layer, the first doped region, and the second doped region. The first conductive layer is located on the substrate. The second conductive layer is located on the first conductive layer. The first dielectric layer is located between the substrate and the first conductive layer. The second dielectric layer is located between the first conductive layer and the second conductive layer. The first doped region and the second doped region are located in the substrate at two sides of the first conductive layer. The second conductive layer is electrically connected to the first doped region and the second doped region. Therefore, the varactor structure of an embodiment above may have a higher quality factor and a higher unit capacitance.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A varactor structure, comprising:
a substrate;
a first conductive layer located on the substrate;
a second conductive layer located on the first conductive layer;
a first dielectric layer located between the substrate and the first conductive layer;
a second dielectric layer located between the first conductive layer and the second conductive layer; and
a first doped region and a second doped region located in the substrate at two sides of the first conductive layer, wherein
the second conductive layer is electrically connected to the first doped region and the second doped region.

2. The varactor structure of claim 1, further comprising:
a first conductive wire electrically connected to the second conductive layer, the first doped region, and the second doped region.

3. The varactor structure of claim 2, wherein a top-view pattern of the first conductive wire comprises a ring shape.

4. The varactor structure of claim 2, further comprising:
a first conductive plug located between the first conductive wire and the second conductive layer and electrically connected to the first conductive wire and the second conductive layer;
a second conductive plug located between the first conductive wire and the first doped region and electrically connected to the first conductive wire and the first doped region; and
a third conductive plug located between the first conductive wire and the second doped region and electrically connected to the first conductive wire and the second doped region.

5. The varactor structure of claim 4, further comprising:
a second conductive wire electrically connected to the first conductive layer.

6. The varactor structure of claim 5, further comprising:
a fourth conductive plug located between the second conductive wire and the first conductive layer and electrically connected to the second conductive wire and the first conductive layer.

7. The varactor structure of claim 1, wherein the first conductive layer and the second conductive layer are extended in a first direction.

8. The varactor structure of claim 7, wherein a length of the first conductive layer in the first direction is greater than a length of the second conductive layer in the first direction.

9. The varactor structure of claim 7, wherein the first doped region and the second doped region are arranged in a second direction, and the first direction is intersected with the second direction.

10. The varactor structure of claim 1, wherein a material of the first conductive layer comprises doped polysilicon or a metal.

11. The varactor structure of claim 1, wherein a material of the second conductive layer comprises a metal, a metal compound, or a combination thereof.

12. The varactor structure of claim 1, wherein a material of the first dielectric layer comprises silicon oxide, a high-k material, or a combination thereof.

13. The varactor structure of claim 1, wherein a material of the second dielectric layer comprises a low-k material or a high-k material.

14. The varactor structure of claim 1, further comprising:
a spacer located on a sidewall of the first conductive layer.

15. The varactor structure of claim 1, further comprising:
a well region located in the substrate, wherein the first doped region and the second doped region are located in the well region.

16. The varactor structure of claim 15, wherein the first doped region, the second doped region, and the well region have a same conductivity type.

17. The varactor structure of claim 1, further comprising:
an isolation structure located in the substrate and defining an active region in the substrate.

18. The varactor structure of claim 17, wherein the first doped region and the second doped region are located in the active region.

19. The varactor structure of claim 17, wherein the isolation structure comprises a shallow trench isolation structure.

20. The varactor structure of claim 1, further comprising:
a third dielectric layer located between the second dielectric layer and the substrate; and
a fourth dielectric layer located on the second dielectric layer.
